(19) United States
(12) Patent Application Publication
(10) Pub. No.: US 2019/0103832 A1
(43) Pub. Date: Apr. 4, 2019

(54) METHOD OF INSPECTING SOLAR CELL MODULE

(71) Applicant: MITSUBISHI ELECTRIC CORPORATION, Chiyoda-ku, Tokyo (JP)

(72) Inventor: Hitoshi Nakamura, Tokyo (JP)

(73) Assignee: MITSUBISHI ELECTRIC CORPORATION, Chiyoda-ku, Tokyo (JP)

(21) Appl. No.: 16/086,657

(22) PCT Filed: Apr. 28, 2016
(86) PCT No.: PCT/JP2016/063486

§ 371 Date: Sep. 20, 2018

(51) Int. Cl. H02S 50/10; G01R 19/00; H01L 31/18; H01L 31/05; H01L 31/044; H01L 31/0725

(52) U.S. Cl. CPC H02S 50/10; G01R 19/0092; H01L 31/0725; H01L 31/0504; H01L 31/044; H01L 31/18

(57) ABSTRACT

Provided is a method for inspecting a solar cell module including a solar cell array. The solar cell array includes a plurality of clusters connected in parallel, and each of the plurality of clusters includes a plurality of solar battery cells connected in series. The method includes measuring a current value of a current flowing through a circuit inside the solar cell module without making contact with the inside circuit to detect a short-circuit fault and an open fault in a first solar cell cluster, a second solar cell cluster, and a third solar cell cluster and a short-circuit fault and an open fault in a first bypass diode, a second bypass diode, and a third bypass diode.

### FIELD

The present invention relates to a method of inspecting a solar cell module for inspecting a solar cell module including a plurality of clusters connected in parallel, each cluster including a plurality of solar battery cells connected in series.

### BACKGROUND

Most solar cell modules are installed outdoors in order to receive sunlight and generate electric power. Therefore, solar cell modules are exposed to various types of stress immediately after installation, such as stress of temperature difference between daytime and nighttime, stress of seasonal temperature fluctuation, stress due to temperature and humidity, and load stress due to strong wind or snowfall.

Even when a solar cell module deteriorates due to various types of stress and the output thereof declines, the solar cell module is less likely to stop its operation, make abnormal noises, or undergo a noticeable change in appearance than other electric instruments. Therefore, the solar cell module with the reduced output is left for a long period of time without being noticed by the user, and loses the electric power that should have originally been generated, causing the problem of opportunity loss of electric power selling in the case of selling electric power.

Patent Literature 1 discloses a method of detecting a fault in a solar cell module. The invention disclosed in Patent Literature 1 provides a signal generating means to the solar cell module so that both a short-circuit fault and an open fault in the solar cell module can be easily detected.

### CITATION LIST

### Patent Literature

Patent Literature It Japanese Patent Application Laid-open No. H11-330521

### SUMMARY

### Technical Problem

However, the invention disclosed in Patent Literature 1 has the following problem: the unit cost of the solar cell module is increased by adding additional parts to the solar cell module, since the signal generating means is also included in the solar cell module, it receives the same environmental stress. If the signal generating means falls due to environmental stress, it becomes difficult to detect a fault in the solar cell module, and the risk of erroneous determination increases.

Therefore, the signal generating means and its peripheral circuit of Patent Literature 1 are required to have reliability equivalent to or higher than the reliability of the solar cell module, in order to ensure further safety, a device which can detect a fault in the signal generating means and the peripheral circuit is additionally required.

The present invention has been made in view of the above circumstances, and an object thereof is to obtain a method of inspecting a solar cell module that enables detection of an open fault and a short-circuit fault in a circuit inside a solar cell module with a simple technique without adding any parts to the solar cell module.

### Solution to Problem

An aspect of the present invention provides a method of inspecting a solar cell module for inspecting a solar cell module including a solar cell array including a plurality of clusters connected in parallel, each cluster including a plurality of solar battery cells connected in series. The present invention includes measuring a current value of a current flowing through a circuit inside the solar cell module without making contact with the circuit to detect a short-circuit fault and an open fault in the circuit.

### Advantageous Effects of Invention

The method of inspecting a solar cell module according to the present invention achieves the effect of enabling detection of an open fault and a short-circuit fault in a circuit of a solar cell module with a simple technique without adding any parts to the solar cell module.

### BRIEF DESCRIPTION OF DRAWINGS

FIG. 1 is a diagram illustrating a configuration of a photovoltaic power generation system with a solar cell module to be inspected with a method of inspecting a solar cell module according to the first embodiment of the present invention.

FIG. 2 is a diagram illustrating a configuration of a solar cell module to be inspected with the method of inspecting a solar cell module according to the first embodiment.

FIG. 3 is a diagram illustrating how the solar cell module operates when a partial cluster of the solar cell module to be inspected with the method of inspecting a solar cell module according to the first embodiment is shaded while the other clusters are irradiated with sunlight normally.

FIG. 4 is a diagram illustrating the concept of the method of inspecting a solar cell module according to the first embodiment.

FIG. 5 is a diagram illustrating the process of the first stage of the method of inspecting a solar cell module according to the first embodiment.

FIG. 6 is a flowchart illustrating the processing flow of the first stage of the method of inspecting a solar cell module according to the first embodiment.

FIG. 7 is a diagram illustrating the process of the second stage of the method of inspecting a solar cell module according to the first embodiment.

FIG. 8 is a flowchart illustrating the processing flow of the second stage of the method of inspecting a solar cell module according to the first embodiment.

FIG. 9 is a diagram illustrating a configuration of a solar cell module to be inspected in an example of the method of inspecting a solar cell module according to the first embodiment.

FIG. 10 is a diagram illustrating the first stage in the example of the method of inspecting a solar cell module according to the first embodiment.

FIG. 11 is a flowchart illustrating the processing flow of the first stage in the example of the method of inspecting a solar cell module according to the first embodiment.

FIG. 12 is a diagram illustrating the second stage in the example of the method of inspecting a solar cell module according to the first embodiment.

FIG. 13 is a flowchart illustrating the processing flow of the second stage in the example of the method of inspecting a solar cell module according to the first embodiment.

FIG. 14 is a diagram illustrating a configuration of a solar cell module to be inspected with a method of inspecting a solar cell module according to the second embodiment of the present invention.

FIG. 15 is a diagram illustrating the first stage in an example of the method of inspecting a solar cell module according to the second embodiment.

FIG. 16 is a flowchart illustrating the processing flow of the first stage in the example of the method of inspecting a solar cell module according to the second embodiment.

FIG. 17 is a diagram illustrating the second stage in the example of the method of inspecting a solar cell module according to the second embodiment.

FIG. 18 is a flowchart illustrating the processing flow of the second stage in the example of the method of inspecting a solar cell module according to the second embodiment.

FIG. 19 is a diagram illustrating the third stage in the example of the method of inspecting a solar cell module according to the second embodiment.

FIG. 20 is a flowchart Illustrating the processing flow of the third stage in the example of the method of inspecting a solar cell module according to the second embodiment.

### DESCRIPTION OF EMBODIMENTS

Hereinafter, methods of inspecting a solar cell module according to embodiments of the present invention will be described in detail based on the drawings. The present invention is not limited to the embodiments.

### First Embodiment

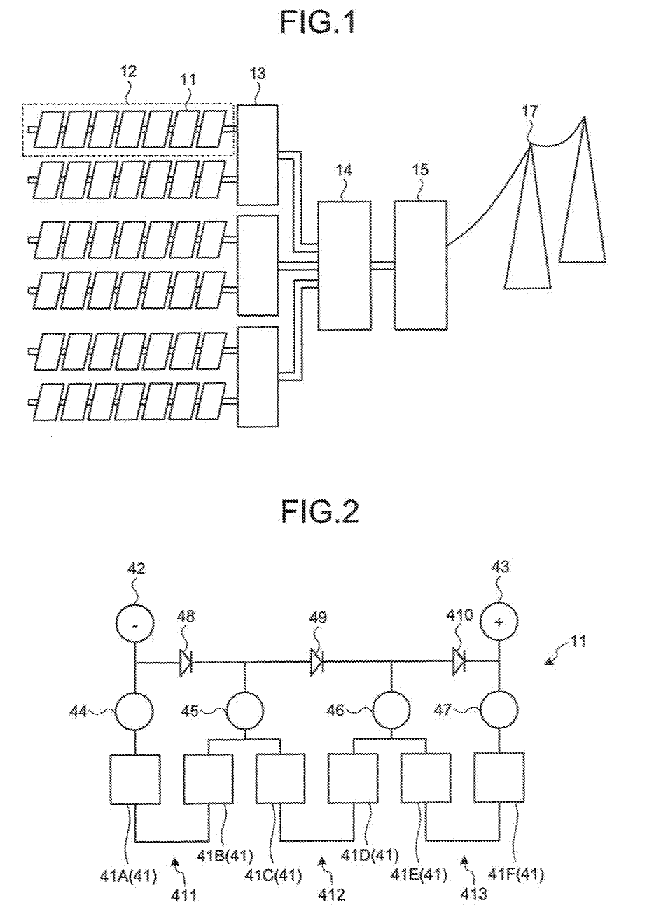

FIG. 1 is a diagram illustrating a configuration of a photovoltaic power generation system with a solar cell module to be inspected with a method of inspecting a solar cell module according to the first embodiment of the present invention. An element in which solar cell modules 11 are connected in series is called a string 12. The number of solar cell modules 11 connected in series in the string 12 is selected within a range not exceeding the system voltage of the photovoltaic power generation system itself.

Strings 12 are connected in parallel to junction boxes 13. In the first embodiment, the junction boxes 13 are further connected in parallel to a current collecting box 14. The number of parallel strings 12 and the number of parallel junction boxes 13 are not limited to a specific number. Generally, increasing the number of parallel strings 12 can increase the current, but increases the transmission loss as well, which causes a reduction in the efficiency of power generation. Further, when the number of solar cell modules 11 connected in series in each string 12 is increased and the number of parallel strings 12 is reduced, the required number of junction boxes 13 and current collecting boxes 14 can be reduced. However, in this case, the voltage of electric power output from the strings 12 increases, and expensive junction boxes 13 and current collecting boxes 14 that support high voltage are required. Thus, the unit costs of the junction box 13 and the current collecting box 14 increase as a result. Therefore, the number of parallel strings 12 and the number of parallel junction boxes 13 are selected in consideration of the trade-off between the magnitude of current and the efficiency of power generation and the trade-off between the required number of junction boxes 13 and current collecting boxes 14 and the unit cost.

DC power collected by the junction boxes 13 and the current collecting box 14 i transmitted to a power conditioner 15, converted into AC power thereafter, and transmitted to a grid 17 connected to the photovoltaic power generation system.

FIG. 2 is a diagram illustrating a configuration of a solar cell module to be inspected with the method of inspecting a solar cell module according to the first embodiment. In the first embodiment, the solar cell module 11 has a general structure in which six rows of clusters each including N solar battery cells are arranged. In the solar cell module 11, six clusters 41 each of which includes N solar battery cells connected in series, are connected in series, and a negative terminal 4 and a positive terminal 43 are located at the two ends thereof. Further, for each region of the solar cell module 11 including two clusters 41 connected in series, a first bypass diode 48, a second bypass diode 49 and a third bypass diode 410 are connected in parallel via a first terminal portion 44, a second terminal portion 45, a third terminal portion 46, and a fourth terminal portion 47. For the sake of convenience of description, when it is necessary to distinguish the six clusters 41, they are referred to as the cluster 41A, the cluster 41E, the cluster 41C, the cluster 41D, the cluster 41E, and the cluster 41F from the end. When collectively referred to, they are simply referred to as the cluster. 41.

When the current stops flowing or hardly flows for some reason to the cluster 41 correspondingly connected in parallel to any of the first bypass diode 48, the second bypass diode 49, and the third bypass diode 410, the diode causes the current that does not flow to the cluster 41 to bypass the cluster 41 in order to avoid causing the hot spot phenomenon, i.e., prevent the cluster 41 from generating heat.

The cluster 41A and the cluster 41B are connected in series to form a first solar cell cluster 411. The cluster 41C and the cluster 41D are connected in series to form a second solar cell cluster 412. The cluster 41B and the cluster 41F are connected in series to form a third solar cell cluster 413. The first solar cell cluster 411, the second solar cell cluster 412, and the third solar cell cluster 413 are sequentially connected in series to form a solar cell array. The first terminal portion 44 is connected to the end of the first solar cell cluster 411. The second terminal portion 45 is connected to the connection between the first solar cell cluster 411 and the second solar cell cluster 412. The third terminal portion 46 is connected to the connection between the second solar cell cluster 412 and the third solar cell cluster 413. The fourth terminal portion 47 is connected to the end of the third solar cell cluster 413.

The first terminal portion 44 and the second terminal portion 45 are connected by the first bypass diode 48. The second terminal portion 45 and the third terminal portion 46 are connected by the second bypass diode 49. The third terminal portion 46 and the fourth terminal portion 47 are connected by the third bypass diode 410.

As described above, inside the solar cell module 11 according to the first embodiment, the cluster 41, the negative terminal 42, the positive terminal 43, the first terminal portion 44, the second terminal portion 45, the third terminal portion 46, the fourth terminal portion 47, the first bypass diode 48, the second bypass diode 49, and the third bypass diode 410 constitute a circuit.

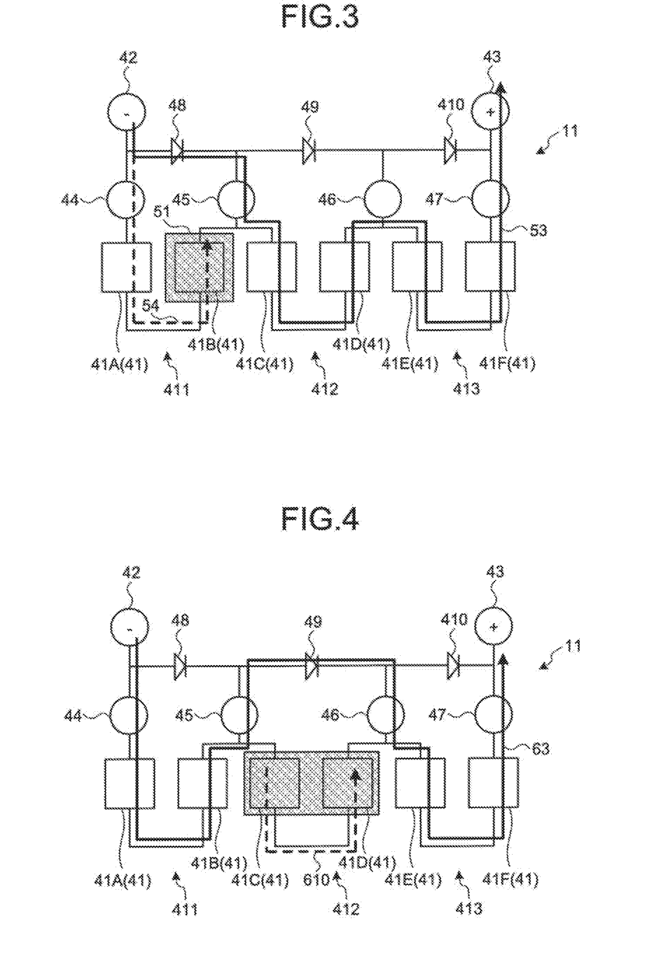

FIG. 3 is a diagram illustrating how the solar cell module operates when a partial cluster of the solar cell module to be inspected with the method of inspecting a solar cell module according to the first embodiment is shaded while the other clusters are irradiated with sunlight normally. In a shadow portion 51 of the cluster 41B, the current generated by sunlight irradiation that is the allowable current that can flow, is reduced, on the other hand, because the amount of current generated in each of the surrounding cluster 41A, cluster 41C, cluster 41D, cluster 41E, and cluster 41F has a normal value, when the first bypass diode 48 is not provided, a bottleneck due to the current difference occurs in the shadow portion 51 of the cluster 41B, and heat is generated.

At the time that a certain amount of current bottleneck occurs, the first bypass diode 48 operates to cause a current 53 and a current 54 to flow through the circuit inside the solar cell module 11. The current 54 flows in a branch leading to the first terminal portion 44 before the first bypass diode 48 and is separated from the current 53. The current 54 then joins the current 53 at a point just after the second terminal portion 45 and just before the cluster 41C. The current 53 flowing through the first bypass diode 48 corresponds to the bottleneck caused by the current difference in the shadow portion 51 of the cluster 41B. On the other hand, the current 54 flowing through the first solar cell cluster 411 is the sum of the leakage current of the solar battery cells in the first solar cell cluster 411 and the allowable current of the first solar cell cluster 411 reduced due to the shadow portion 51. Therefore, the operation of the first bypass diode 48 eliminates the bottleneck caused in the shadow portion 51 of the cluster 41B and also eliminates heat generation.

The operating condition for the first bypass diode 48 depends on the number of clusters 41 connected in series and the allowable current reduced by shielding. The allowable current reduced by shielding is obtained using the ratio of light that is blocked by shielding and does not reach a solar battery cell, with the current in the unshielded state taken as 100%. Therefore, the allowable current reduced by shielding depends on parameters such as shadow density and shielded area. For example, when a black body that does not pass light at all is closely attached to an area of 50% of one solar battery cell for shielding, the allowable current is 50% lower than the current in the unshielded state.

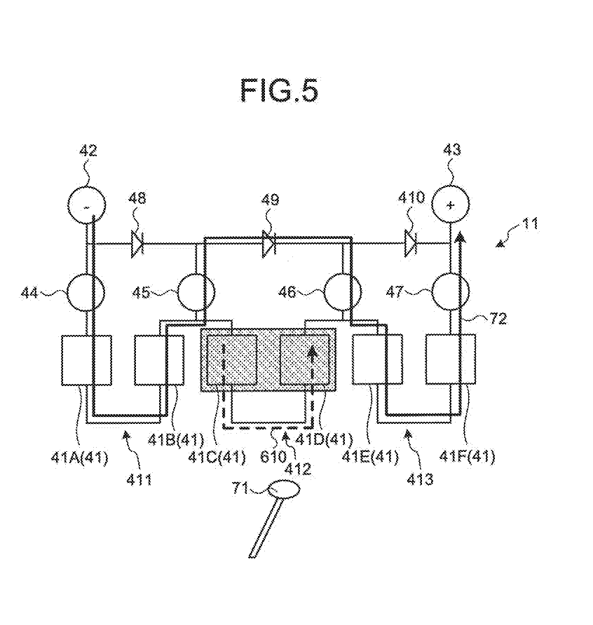

FIG. 4 is a diagram illustrating the concept of the method of inspecting a solar cell module according to the first embodiment, in the solar cell module 11 operating as a part of the system, the operating current is measured in the unshielded state, and then the second solar cell cluster 412 is shielded. The shielding level, that is, shadow density and shadow area for shielding, is equal to or more than a level that satisfies the condition for operating the second bypass diode 49 connected in parallel to the second solar cell cluster 412. Note that it is unnecessary to shield both the cluster 41C and the cluster 41D as illustrated in FIG. 4. Only one of the cluster 41C and the cluster 41D may be shielded as long as the current flowing through the second solar cell cluster 412 is hindered to cause a bottleneck and operate the second bypass diode 49.

When the second solar cell cluster 412 is shielded, a current 63 flows through the circuit inside the solar cell module 11 in the following order: the negative terminal 42, the first terminal portion 44, the cluster 41A, the cluster 41B, the second terminal portion 45, the second bypass diode 49, the third terminal portion 46, the cluster 41E, the cluster 41F, the fourth terminal portion 47 and the positive terminal 43. A current 610 that flows through the shielded second solar cell cluster 412 flows in a branch starting just before the second terminal portion 45, flows to the cluster 41C and to the cluster 41D, and joins the current 63 just after the third terminal portion 46 and just before the cluster 41E. It should be noted that the value of the current 610 is the sum of the leakage current of the second solar cell cluster 412 and the allowable current of the second solar cell cluster 412 reduced by shielding. In this manner, the second bypass diode 49 operates by shielding the second solar cell cluster 412, and the current path and the current value in the circuit change. In this state, current measurement is performed on each part of the solar cell module 11, so that open faults and short-circuit faults can be detected.

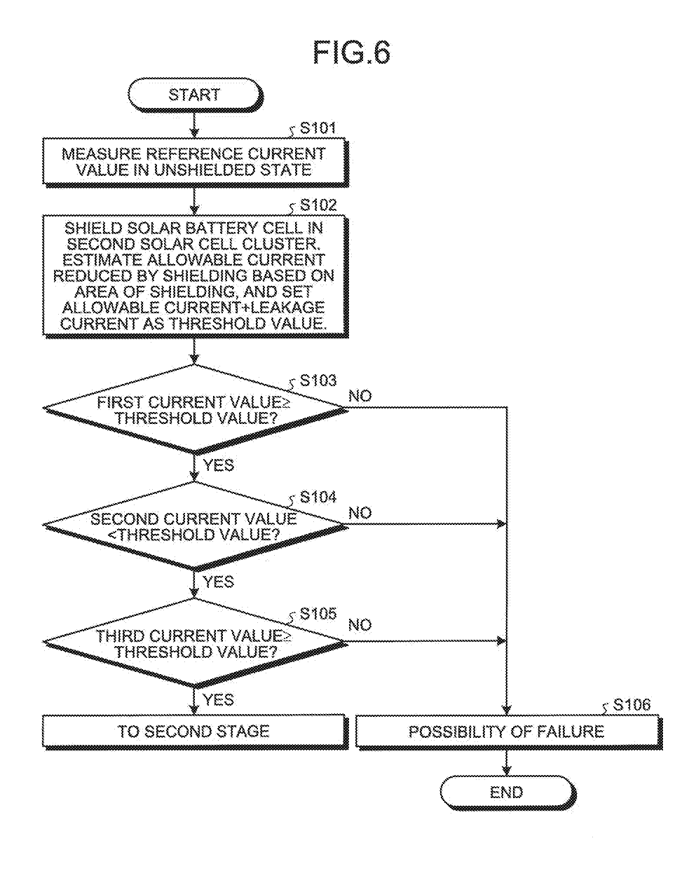

FIG. 5 is a diagram illustrating the process of the first stage of the method of inspecting a solar cell module according to the first embodiment. FIG. 6 is a flowchart illustrating the processing flow of the first stage of the method of inspecting a solar call module according to the first embodiment. In step S101, the operating current is measured in the unshielded state as a reference current value. That is, the reference current value flowing through the solar cell module 11 is measured in a state where the first solar cell cluster 411, the second solar cell cluster 412, and the third solar cell cluster 413 are not shielded. In step S102, a solar battery cell in the second solar cell cluster 412 is shielded, the allowable current reduced by shielding is estimated based on the area of shielding, and the sum of the allowable current and the leakage current is set as a threshold value. Because the allowable current reduced by shielding greatly depends on fluctuations in the amount of solar radiation, it is desirable that determination be performed in as stable a solar radiation condition as possible or in a state where the allowable current becomes substantially zero, that is, in a state where one solar battery cell that belongs to each cluster is 100% covered. However, in order to completely shield one solar battery cell, it is necessary to precisely align a shielding member with the solar battery cell, shielding a part of the solar battery cell can simplify the alignment operation between the shielding member and the solar battery cell. The threshold value may be the leakage current of the solar battery cells in the second solar cell cluster 412.

In step S103, a first current value which is the value of the current flowing through the first solar cell cluster 411 is measured, and it is determined whether the first current value is equal to or greater than the threshold value set in step S102. If the first current value is less than the threshold value set in step S102, “No” is selected in step S103. Therefore, the process proceeds to step S106, where it is determined that there is a possibility of failure, and the process is terminated. If the first current value is equal to or greater than the threshold value set in step S102, “Yes” is selected in step S103. Therefore, the process proceeds to step S104. In step S104, it is determined whether a second current value which is the value of the current flowing through the second solar cell cluster 412 is less than the threshold value set in step S102. If the second current value is equal to or greater than the threshold value set in step S102, “No” is selected in step S104. Therefore, the process proceeds to step S106, where it is determined that there is a possibility of failure, and the process is terminated. If the second current value is less than the threshold value set in step S102, “Yes” is selected in step S104. Therefore, the process proceeds to step S105. In step S105, a third current value which is the value of the current flowing through the third solar cell cluster 413 is measured, and it is determined whether the third current value is equal to or greater than the threshold value set in step S102. If the third current value is less than the threshold value set in step S102, “No” is selected in step S105. Therefore, the process proceeds to step S106, where it is determined that there is a possibility of failure, and the process is terminated. If the third current value is equal to or greater than the threshold value set in step S102, “Yes” is selected in step S105. Therefore, the process of the second stage to be described later is executed.

In steps S103, S104, and S105, the current flowing through the solar cell module 11 is detected using a sensor 71 through the front glass, the back glass, or the back film. Specifically, an inspection is performed by scanning wires visible from the front or back surface of the solar cell module 11 using a measuring device, which incorporates a sensor that detects the value of a current based on a fluctuation in the magnetic field and informs a measurer in response to the value exceeding the threshold value. There are various types of sensors 71 such as a sensor that detects a change in the magnetic field due to the flowing current, but any type of sensor 71 may be used as long as it can accurately detect a current without making contact. In addition, in the case of using a sensor that sounds a buzzer in response to the current exceeding the threshold value instead of a sensor that obtains a measured current value, in step S102, the threshold value is set to such a level that any current equal to or less than the current 610, which is the sum of the leakage current of the solar battery cells 111 in the second solar cell cluster 412 and the allowable current of the second solar cell cluster 412 reduced by shielding, is not detected.

When the second solar cell cluster 412 is shielded, a current 72 flows through the circuit inside the solar cell module 11 in the following order: the negative terminal 42, the first terminal portion 44, the cluster 41A, the cluster 41B, the second terminal portion 45, the second bypass diode 49, the third terminal portion 46, the cluster 41E, the cluster 41F, the fourth terminal portion 47, and the positive terminal 43. In the general solar cell module 11, the negative terminal 42, the positive terminal 43, the first terminal portion 44, the second terminal portion 45, the third terminal portion 46, the fourth terminal portion 47, the first bypass diode 48, the second bypass diode 49, and the third bypass diode 410 are contained in a terminal box and often difficult to access. Therefore, it is desirable that the presence or absence of a current be intuitively detected in a region visible through the glass surface or back film surface such as the cluster 41A, the cluster 41B, the cluster 41C, the cluster 41D, the cluster 41E, and the cluster 41F. Here, the presence or absence of a current is checked in the first solar cell cluster 411, the second solar cell cluster 412, and the third solar cell cluster 413.

When an open fault occurs in the path connecting the negative terminal 42, the first terminal portion 44, the cluster 41A, the cluster 41B, and the second terminal portion 45 in this order, no current is detected in the first solar cell cluster 411. Similarly, when a short-circuit fault occurs at the first bypass diode 48, no current can b detected in the first solar cell cluster 411.

When an open fault occurs in the path connecting the third terminal portion 46, the cluster 41E, the cluster 41F, the fourth terminal portion 47, and the positive terminal 43 in this order, no current is detected in the third solar cell cluster 413. Similarly, when a short-circuit fault occurs at the third bypass diode 410, no current can be detected in the third solar call cluster 413.

When an open fault occurs in the path connecting the second terminal portion 45, the second bypass diode 49, and the third terminal portion 46 in this order, the current flowing through the solar cell module 11 is forced to pass through the second solar cell cluster 412 including the shielded solar battery cell 111. Therefore, the current in the second solar cell cluster 412 is greater than the current 610, which is the sum of the leakage current of the solar battery cells 111 in the second solar cell cluster 412 and the allowable current of the second solar cell cluster 412 reduced by shielding.

Thus, by shielding the second solar cell cluster 412 and measuring the first current value, the second current value, and the third current value, an open fault in the first solar cell cluster 411 or the third solar cell cluster 413, a short-circuit fault in the first bypass diode 48 or the third bypass diode 410, and an open fault in the second bypass diode 49 can be detected.

In the above explanation, the first current value, the second current value, and the third current value are separately measured in steps S103 to S105, and are compared with the threshold value after each measurement. Alternatively, the first current value, the second current value, and the third current value may be measured first, and may then be sequentially compared with the threshold value.

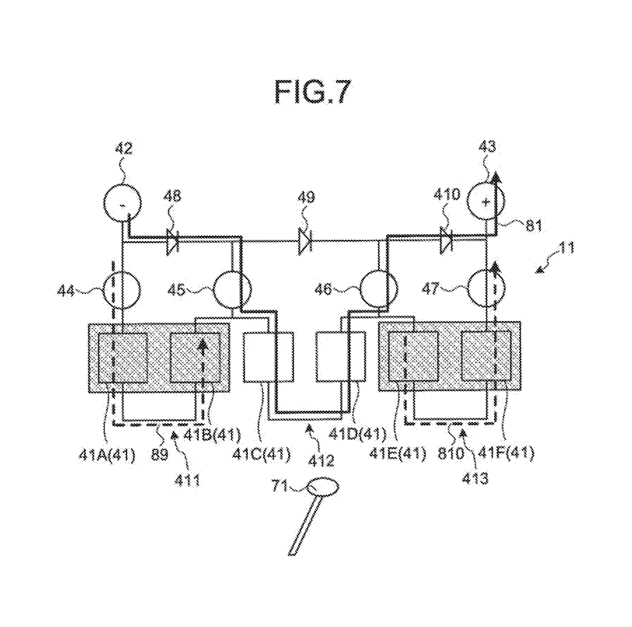

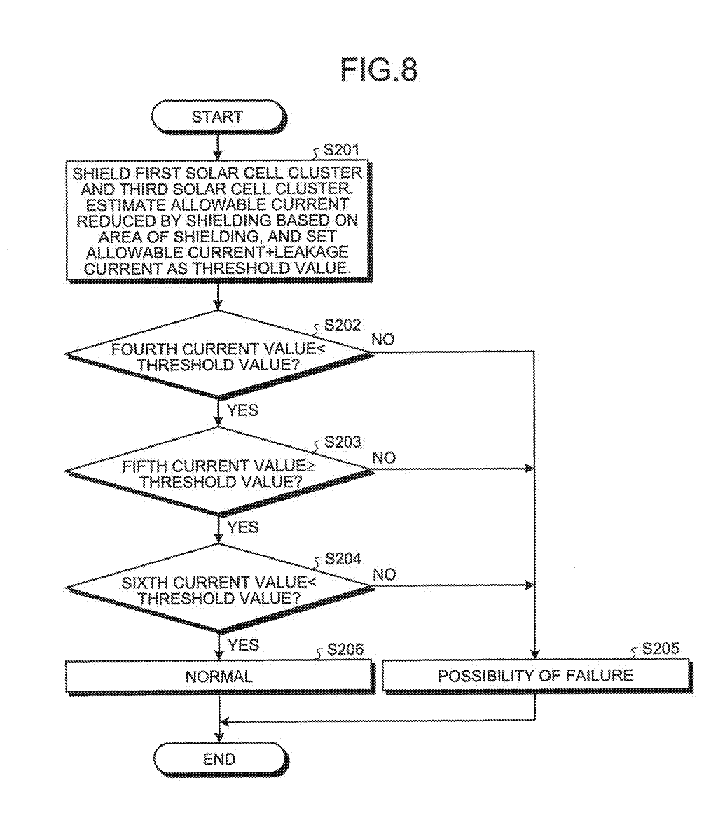

FIG. 7 is a diagram illustrating the process of the second stage of the method of inspecting a solar cell module according to the first embodiment. FIG. 8 is a flowchart illustrating the processing flow of the second stage of the method of inspecting a solar cell module according to the first embodiment. In step S201, the first solar cell cluster 411 and the third solar cell cluster 413 are shielded, the allowable current reduced by shielding is estimated based on the area of shielding as in the first stage described with reference to FIG. 5, and the sum of the allowable current and the leakage current is set as a threshold value. In step S202, a fourth current value which is the value of the current flowing through the first solar cell cluster 411 is measured, and it is determined whether the fourth current value is less than the threshold value set in step S201. If the fourth current value is equal to or greater than the threshold value set in step S201, “No” is selected in step S202. Therefore, the process proceeds to step S205, where it is determined that there is a possibility of failure, and the process is terminated. If the fourth current value is less than the threshold value set in step S201, “Yes” is selected in step S202. Therefore, the process proceeds to step S203.

In step S203, a fifth current value which is the value of the current flowing through the second solar cell cluster 412 is measured, and it is determined whether the fifth current value is equal to or greater than the threshold value set in step S201. If the fifth current value is less than the threshold value set in step S201, “No” is selected in step S203. Therefore, the process proceeds to step S205, where it is determined that there is a possibility of failure, and the process is terminated. If the fifth current value is equal to or greater than the threshold value set in step S201, “Yes” is selected in step S203. Therefore, the process proceeds to step S204.

In step S204, a sixth current value which is the value of the current flowing through the third solar cell cluster 413 is measured, and it is determined whether the sixth current value is less than the threshold value. If the sixth current value is equal to or greater than the threshold value set in step S201, “No” is selected in step S204. Therefore, the process proceeds to step S205, where it is determined that there is a possibility of failure, and the process is terminated. If the sixth current value is less than the threshold value set in step S201, “Yes” is selected in step S204. Therefore, it is determined in step S206 that the solar cell module 11 is normal, and the process is terminated.

In step S202, step S203, and step S204, the fourth current value, the fifth current value, and the sixth current value are detected using the sensor 71 through the front glass, the back glass, or the back film. There are various types of sensors 71 such as a sensor that detects a change in the magnetic field due to the flowing current, but any type of sensor 71 may be used as long as it can accurately detect a current without making contact. In addition, in the case of using a sensor that sounds a buzzer in response to the current exceeding a certain threshold value instead of a sensor that obtains a measured current value, in step S201, the threshold value is set to such a level that any current equal to or less than a current 89, which is the sum of the leakage current of the first solar cell cluster 411 and the allowable current of the first solar cell cluster 411 reduced by shielding, and equal to or less than a current 810, which is the sum of the leakage current of the third solar cell cluster 413 and the allowable current of the third solar cell cluster 413 reduced by shielding, is not detected.

When the first solar cell cluster 411 and the third solar cell cluster 413 are shielded, a current 81 flows through the circuit inside the solar cell module 11 in the following order: the negative terminal 42, the first bypass diode 48, the second terminal portion 45, the cluster 41C, the cluster 41D, the third terminal portion 46 the third bypass diode 410, and the positive terminal 43. The current 89 for the shielded first solar cell cluster 411 flows in a branch just before the first bypass diode 48, flows through the first terminal portion 44, the cluster 41A, and the cluster 41B in this order, and joins the current 81 starting just after the second terminal portion 45 and just before the cluster 41C. The value of the current 89 is the sum of the leakage current of the first solar cell cluster 41l and the allowable current of the first solar cell cluster 411 reduced by shielding. The current 810 for the third solar cell cluster 413 flows in a branch staring just before the third terminal portion 46, flows through the cluster 41E, the cluster 41F, and the fourth terminal portion 47 in this order, and joins the current 81 just after the third bypass diode 410. The value of the current 810 is the sum of the leakage current of the third solar cell cluster 413 and the allowable current of the third solar cell cluster 413 reduced by shielding. As described above, it is desirable that the presence or absence of a current be intuitively detected in a region visible through the glass surface or back film surface such as the cluster 41A, the cluster 41B, the cluster 41C, the cluster 41D, the cluster 41E, and the cluster 41F. Here, the presence or absence of a current is checked in the first, solar cell cluster 411, the second solar cell cluster 412, and the third solar cell cluster 413.

When an open fault occurs in the path connecting the second terminal portion 45, the cluster 41C, the cluster 41D, and the third terminal portion 46 in this order, no current is detected in the second solar cell cluster 412. Similarly, when a short-circuit fault occurs at the second bypass diode 49, no current can be detected in the second solar cell cluster 412.

When an open fault occurs in the path connecting the negative terminal 42, the first bypass diode 48, and the second terminal portion 45 in this order, the current flowing through the solar cell module 11 is forced to pass through the shielded first solar cell cluster 411. Therefore, the current in the first solar cell cluster 411 is greater than the current 89, which is the sum of the leakage current of the first solar cell cluster 411 and the allowable current of the first solar cell cluster 411 reduced by shielding.

When an open fault occurs in the path connecting the third terminal portion 46, the third bypass diode 410, and the positive terminal 43 in this order, the current flowing through the solar cell module 11 is forced to pass through the shielded third solar cell cluster 413. Therefore, the current in the third solar cell cluster 413 is greater than the current 810, which is the sum of the leakage current of the third solar cell cluster 413 and the allowable current of the third solar cell cluster 413 reduced by shielding.

Thus, by shielding the first solar cell cluster 411 and the third solar cell cluster 413 and measuring the fourth current value, the fifth current value, and the sixth current value, an open fault in the first bypass diode 48 or the third bypass diode 410, an open fault in the second solar cell, cluster 412, and a short-circuit fault in the second bypass diode 49 can be detected.

In the above explanation, the fourth current value, the fifth current value, and the sixth current value are separately measured in steps S202 to S204, and are compared with the threshold value after each measurement. Alternatively, the fourth current value, the fifth current value, and the sixth current value may be measured first, and may than be sequentially compared with the threshold value.

In the method of inspecting a solar cell module according to the first embodiment, a part of the solar cell module 11 connected to the photovoltaic power generation system and operating is shielded, and the bypass diodes are operated. At that time, the front or back surface of the solar cell module 11 is scanned using a sensor capable of detecting a current without making contact. If the solar cell module 11 is normal, the path through which the current flows is unequily determined depending on the shielded place. Therefore, if the current detected in the path satisfies the condition specified by the threshold value, it is determined that the solar cell module 11 is normal, and if the current does not satisfy the condition, it is determined that the solar cell module 11 is abnormal. In the first embodiment, the bypass diodes are operated mainly by applying a plate or the like for shielding, but any technique may be used as long as the bypass diodes can be operated.

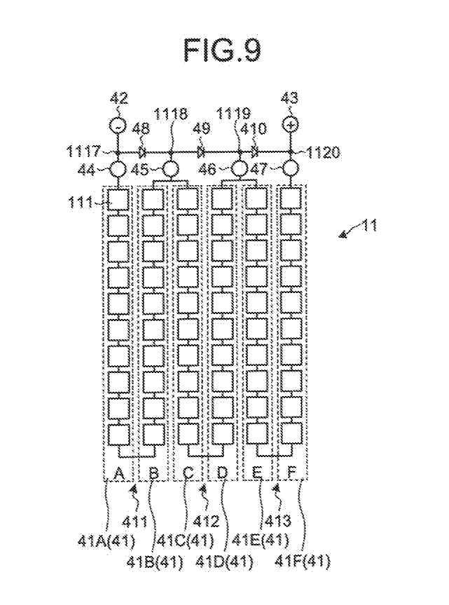

An example of the method of inspecting a solar cell module according to the first embodiment will be described. FIG. 9 is a diagram illustrating a configuration of a solar cell module to be inspected in the example of the method of inspecting a solar cell module according to the first embodiment. The cluster 41 includes ten solar battery cells 111 connected in series. The branch point between the first bypass diode 48 and the first terminal portion 44 is defined as a branch point 1117. The branch point between the first bypass diode 48, the second bypass diode 49, and the second terminal portion 45 is defined as a branch point 1118. The branch point between the second bypass diode 49, the third bypass diode 410, and the third terminal portion 46 is defined as a branch point 1119. The branch point between the third bypass diode 410 and the fourth terminal portion 47 is defined as a branch point 1120.

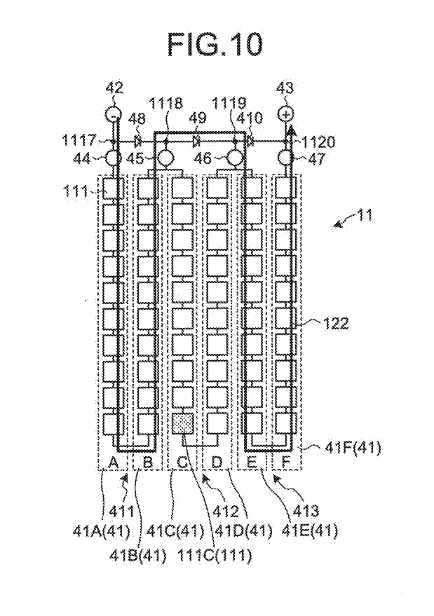

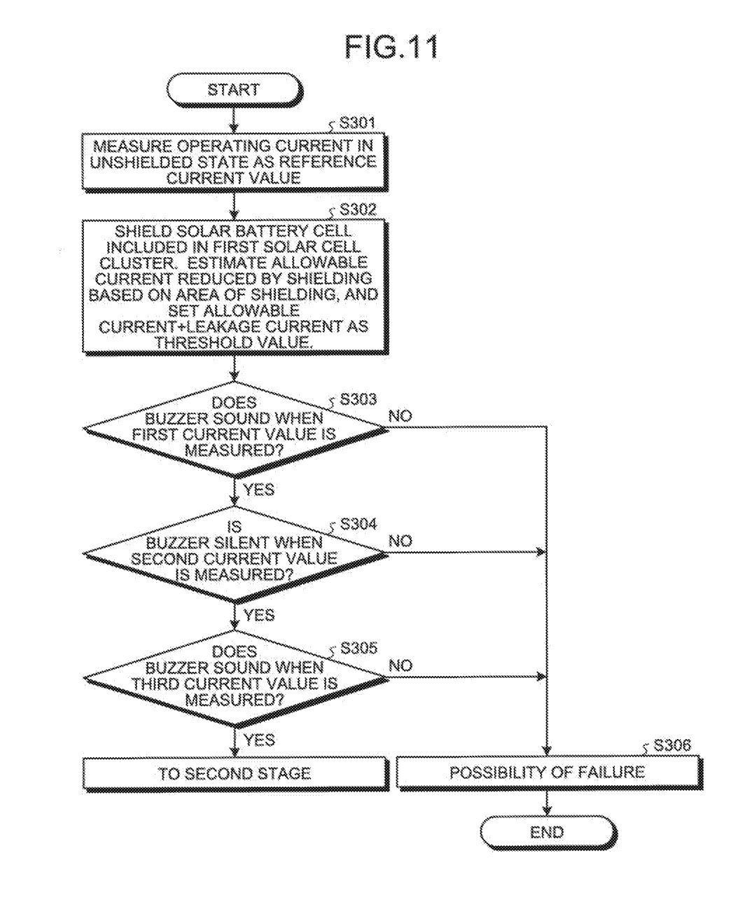

FIG. 10 is a diagram illustrating the first stage in the example of the method of inspecting a solar cell module according to the first embodiment, FIG. 11 is a flowchart illustrating the processing flow of the first stage in the example of the method of inspecting a solar cell module according to the first embodiment. In step S301, in the solar cell module 11 operating as a part of the photovoltaic power generation system, the operating current is measured in the unshielded state as a reference current value. In step S302, the solar battery cell 111C included in the cluster 41C is shielded. The shielded state of the solar battery cell 111C is such that the entire surface of the cell is covered with a black rubber sheet having a thickness of about 5 mm, and no sunlight enters the shielded solar battery cell 111C at all. In this state, no current except the leakage current of the solar battery cell 111C flows in the second solar cell cluster 412 that includes the shielded solar battery cell 111C, and the second bypass diode 49 operates. The operation of the second bypass diode 49 causes a main current 122 of the circuit inside the solar cell module 11 to take the following route: the negative terminal 42, the branch point 1117, the first terminal portion 44, the cluster 41A, the cluster 41B, the second terminal portion 45, the branch point 1118, the second bypass diode 49, the branch point 1119, the third terminal portion 46, the cluster 41E, the cluster 41F, the fourth terminal portion 47, the branch point 1120, and the positive terminal 43.

Further, the allowable current reduced by shielding is estimated based on the area of shielding, and the sum of the allowable current and the leakage current is set as a threshold value of buzzer sounding.

Ideally, the threshold value is set in step S302 using the leakage current of the solar battery cell 111C, but if the leakage current of the solar battery cell 111C is not known, the threshold value may be set using a specification value.

In step S303, the first current value is measured by scanning the wires located in the first solar cell cluster 411 using a current sensor that detects a current with a change in the magnetic field and sounds a buzzer in response to the current exceeding the threshold value set in step S302, and it is checked whether the buzzer sounds when the first current value is measured. If the buzzer does not sound when the first current value is measured, “No” is selected in step S303. Therefore, the process proceeds to step S306, where it is determined that there is a possibility of failure, and the process is terminated. If the buzzer sounds when the first current value is measured, “Yes” is selected in step S303. Therefore, the process proceeds to step S304.

In step S304, the second current value is measured by scanning the wires located in the second solar cell cluster 412 using a current sensor that detects a current with a change in the magnetic field and sounds a buzzer in response to the current exceeding the threshold value set in step S302, and it is checked whether the buzzer is silent when the second current value is measured. If the buzzer sounds when the second current value is measured, “No” is selected in step S304. Therefore, the process proceeds to step S306, where it is determined that there is a possibility of failure, and the process is terminated. If the buzzer is silent when the second current value is measured, “Yes” is selected in step S304. Therefore, the process proceeds to step S305.

In step S305, the third current value is measured by scanning the wires located in the third solar cell cluster 413 using a current sensor that detects a current with a change in the magnetic field and sounds a buzzer in response to the current exceeding the threshold value set in step S302, and it is checked whether the buzzer sounds when the third current value is measured* if the buzzer does not sound when the third current value is measured, “No” is selected in step S305. Therefore, the process proceeds to step S306, where it is determined that there is a possibility of failure, and the process is terminated. If the buzzer sounds when the third current value is measured, “Yes” is selected in step S305. Therefore, the process of the second stage to be described later is executed.

When an open fault occurs in the path connecting the negative terminal 42, the branch point 1117, the first terminal portion 44, the cluster 41A, the cluster 41B, the second terminal portion 45, and the branch point 1118 in this order, or when a short-circuit fault occurs at the first bypass diode 48, the current in the first solar cell cluster 411 is equal to or less than the leakage current of the solar battery cell me, and the buzzer does not sound.

When an open fault occurs in the path connecting the branch point 1119, the third terminal portion 46, the cluster 41E, the cluster 41F, the fourth terminal portion 47, the branch point 1120, and the positive terminal 43 in this order, or when a short-circuit fault occurs at the third bypass diode 410, the current in the third solar cell cluster 413 is equal to or less than the leakage current of the solar battery cells 111C, and the buzzer does not sound.

When an open fault occurs in the path connecting the branch point 1118, the second bypass diode 49, and the branch point 1119 in this order, the current flowing through the solar cell module 11 is forced to pass through the second solar cell cluster 412 that includes the shielded solar battery cell 111C. Therefore, the current in the second solar cell cluster 412 is greater than the leakage current of the solar battery cell 111C, and the buzzer sounds.

Thus, by shielding the solar battery cell 111C and measuring the first current value, the second current value, and the third current value, an open fault in the first solar cell cluster 411 or the third solar cell cluster 413, a short-circuit fault in the first bypass diode 48 or the third bypass diode 410, and an open fault in the second bypass diode 49 can be detected.

In the above explanation, the entire surface of one solar battery cell 111C included in the cluster 41C is shielded. However, because the purpose of shielding is to operate the second bypass diode 49, no restrictions are imposed on the shielding condition such as shielded area and shadow density for shielding as long as the condition for operating the second bypass diode 49 is satisfied. However, as described above, it is possible to reduce the possibility of erroneous determination due to fluctuations in the amount of solar radiation by making determinations with one solar battery cell 111C completely covered.

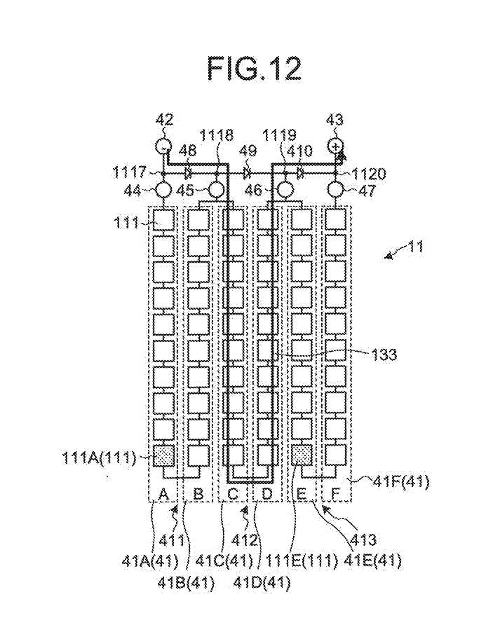

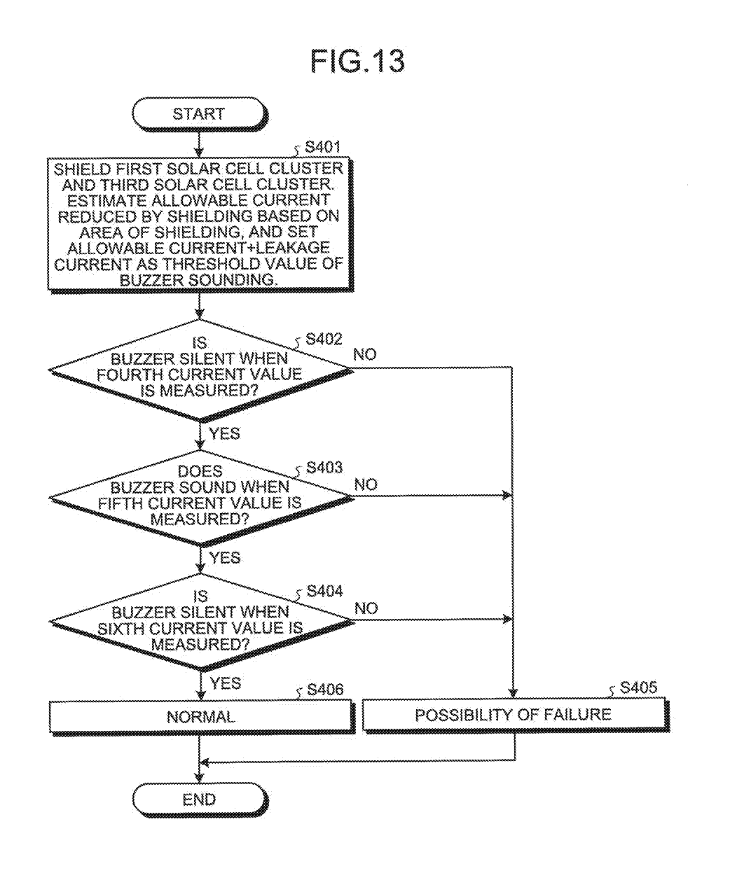

FIG. 12 is a diagram illustrating the second stage in the example of the method of inspecting a solar cell module according to the first embodiment. FIG. 13 is a flowchart illustrating the processing flow of the second stage in the example of the method of inspecting a solar cell module according to the first embodiment. In step S401, in the solar cell module 11 operating as a part of the photovoltaic power generation system, the solar battery cell 111A included in the cluster 41A and the solar battery cell 111E included in the cluster 41E are shielded. The shielded state of the solar battery cells 111A and 111E is such that the entire surface of each cell is covered with a black rubber sheet having a thickness of about 5 mm, and no sunlight enters the shielded solar battery cells 111A and 111B at all. In this state, no current except the leakage current of the solar battery cell 111A flows in the first solar cell cluster 411 including the shielded solar battery cell 111A, and the first bypass diode 48 operates. In addition, no current except the leakage current of the solar battery cell 111E flows in the third solar cell cluster 413 that includes the shielded solar battery cell 111E, and the third bypass diode 410 operates.

When the first solar cell cluster 411 and the third solar cell cluster 413 are shielded, a current 133 flows through the circuit inside the solar cell module 11 in the following order: the negative terminal 42, the branch point 1117, the first bypass diode 48, the branch point 1118, the second terminal portion 45, the cluster 41C, the cluster 41D, the third terminal portion 46, the branch point 1119, the third bypass diode 410, the branch point 1120, and the positive terminal 43.

The allowable current reduced by shielding is estimated based on the area of shielding, and the sum of the allowable current and the leakage current is set as a threshold value of buzzer sounding.

Ideally, the threshold value is set in step S401 using the lower of the leakage current values of the solar battery cell 111A and the solar battery cell 111B, but if these values are not known, the threshold value may be set using a specification value.

In step S402, the fourth current value is measured by scanning the wires located in the first solar cell cluster 411 using a current sensor that detects a current with a change in the magnetic field and sounds a buzzer in response to the current exceeding the threshold value set in step S401, and it is checked whether the buzzer is silent when the fourth current value is measured. If the buzzer sounds when the fourth current value is measured, “No” is selected in step S402. Therefore, the process proceeds to step S405, where it is determined that there is a possibility of failure, and the process is terminated. If the buzzer is silent when the fourth current value is measured, “Yes” is selected in step S402. Therefore, the process proceeds to step S403.

In step S403, the fifth current value is measured by scanning the wires located in the second solar cell cluster 412 using a current sensor that detects a current with a change in the magnetic field and sounds a buzzer in response to the current exceeding the threshold value set in step S401, and it is checked whether the buzzer sounds when the fifth current value is measured. If the buzzer does not sound when the fifth current value is measured, “No” is selected in step S403. Therefore, the process proceeds to step S405, where it is determined that there is a possibility of failure, and the process is terminated. If the buzzer sounds when the fifth current value is measured, “Yes” is selected in step S403. Therefore, the process proceeds to step S404.

In step S404, the sixth current value is measured by scanning the wires located in the third solar cell cluster 413 using a current sensor that detects a current with a change in the magnetic field and sounds a buzzer in response to the current exceeding the threshold value set in step S401, and it is checked whether the buzzer is silent when the sixth current value is measured. If the buzzer sounds when the sixth current value is measured, “No” is selected in step S404. Therefore, the process proceeds to step S405, where it is determined that there is a possibility of failure, and the process is terminated. If the buzzer is silent when the sixth current value is measured, “Yes” is selected in step S404. Therefore, it is determined in step S406 that the solar cell module 11 is normal, and the process is terminated.

When an open fault occurs in the path connecting the branch point 1118, the second terminal portion 45, the cluster 41C, the cluster 41D, the third terminal portion 46, and the branch point 1119 in this order, or when a short-circuit fault occurs at the second bypass diode 49, the current in the second solar cell cluster 412 is equal to or less than the leakage current of the solar battery cell 111A or the solar battery cell 111E, and the buzzer does not sound.

When an open fault occurs in the path connecting the branch point 1117, the first bypass diode 48, and the branch point 1118 in this order, the current flowing through the solar cell module 11 is forced to pass through the first solar cell cluster 411 that includes the shielded solar battery cell 111A. Therefore, the current in the first solar cell cluster 411 is greater than the leakage current of the solar battery cell 111A, and the buzzer sounds.

When an open fault occurs in the path connecting the branch point 1119, the third bypass diode 410, and the branch point 1120 in this order, the current flowing through the solar cell module 11 is forced to pass through the third solar cell cluster 413 that includes the shielded solar battery cell 111E. Therefore, the current in the third solar cell cluster 413 is greater than the leakage current of the solar battery cell 111E, and the buzzer sounds.

Thus, by shielding the solar battery cells 111A and 111E and measuring the fourth current value, the fifth current value, and the sixth current value, an open fault in the first bypass diode 46 or the third bypass diode 410, an open fault in the second solar cell cluster 412, and a short-circuit fault in the second bypass diode 49 can be detected.

In the above explanation, the entire surface of one solar battery cell 111A included in the cluster 41A and the entire surface of one solar battery cell 111E included in the cluster 41E are shielded. However, because the purpose of shielding the solar battery cell 111A is to operate the first bypass diode 48 and the purpose of shielding the solar battery cell 111E is to operate the third bypass diode 410, no restrictions are imposed on the shielding condition as long as the condition for operating the first bypass diode 48 and the third bypass diode 410 is satisfied. However, as described above, it is possible to reduce the possibility of erroneous determination due to fluctuations in the amount of solar radiation by making determinations with one solar battery cell 111A and one solar battery cell 111E completely covered.

By performing the operation according to the flowcharts illustrated in FIGS. 11 and 13, in the solar cell module 11 including six clusters 41 each including ten solar battery cells 111 connected in series, the presence or absence of an open fault and a short-circuit fault in the circuit inside the module can be checked.

The method of inspecting a solar cell module according to the first embodiment enables detection of an open fault and a short-circuit fault in a circuit of a solar cell module with a simple technique without adding any parts to the solar cell module. Further, according to the first embodiment, because the solar cell module can be inspected during the operation of the photovoltaic power generation system, a large-scale system stop is unnecessary, and it is possible to effectively utilize generated electric power. Therefore, the method of inspecting a solar cell module according to the first embodiment can minimize the opportunity loss of electric power selling in the case of selling electric power.

### Second Embodiment

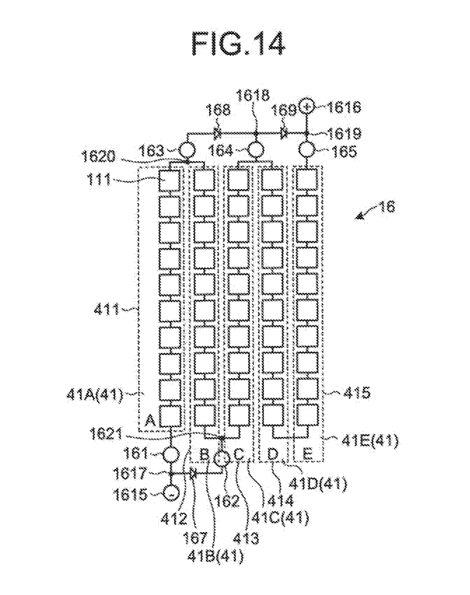

FIG. 14 is a diagram illustrating a configuration of a solar cell module to be inspected with a method of inspecting a solar cell module according to the second embodiment of the present invention. The same reference numerals are given to the same parts as the parts in the first embodiment, and the description thereof will be omitted. In the solar cell module 16 to be inspected in the second embodiment, five clusters 41A, 41B, 41C, 41D, and 41E are connected in series.

The cluster 41A forms the first solar cell cluster 411. The cluster 41B forms the second solar cell cluster 412. The cluster 41C forms the third solar cell cluster 413. The cluster 41D forms a fourth solar cell cluster 414. The cluster 41E forms a fifth solar cell cluster 415. The first solar cell cluster 411, the second solar cell cluster 412, the third solar cell cluster 413, the fourth solar cell cluster 414, and the fifth solar cell cluster 415 are sequentially connected in series to form a solar cell array.

A first terminal portion 161 is connected to the end of the first solar cell cluster 411. A third terminal portion 163 is connected to the connection between the first solar cell cluster 411 and the second solar cell cluster 412. A second terminal portion 152 is connected to the connection between the second solar cell cluster 412 and the third solar cell cluster 413. A fourth terminal portion 164 is connected to the connection between the third solar cell cluster 413 and the fourth solar cell cluster 414. A fifth terminal portion 165 is connected to the end of the fifth solar cell cluster 415.

The first terminal portion 161 and the second terminal portion 152 are connected by a first bypass diode 167. The third terminal portion 163 and the fourth terminal portion 164 are connected by a second bypass diode 168. The fourth terminal portion 164 and the fifth terminal portion 165 are connected by a third bypass diode 169.

Further, a negative terminal 1615 and a positive terminal 1616 are formed at the two ends of the solar cell module 16.

Here, the branch point between the first bypass diode 167 and the first terminal portion 161 is defined as a branch point 1617. The branch point between the second bypass diode 168 and the fourth terminal portion 164 is defined as a branch point 1618. The branch point between the third bypass diode 169 and the fifth terminal portion 165 is defined as a branch point 1619. Further, the branch point between the cluster 41A, the cluster 41B, and the third terminal portion 163 is defined as a branch point 1620. The branch point between the cluster 41B, the cluster 41C, and the second terminal portion 162 is defined as a branch point 1621.

As described above, inside the solar cell module 16 according to the second embodiment, the cluster 41, the negative terminal 1615, the positive terminal 1616, the first terminal portion 161, the second terminal portion 162, the third terminal portion 163, the fourth terminal portion 164, the fifth terminal portion 165, the first bypass diode 167, the second bypass diode 168, and the third bypass diode 169 constitute a circuit.

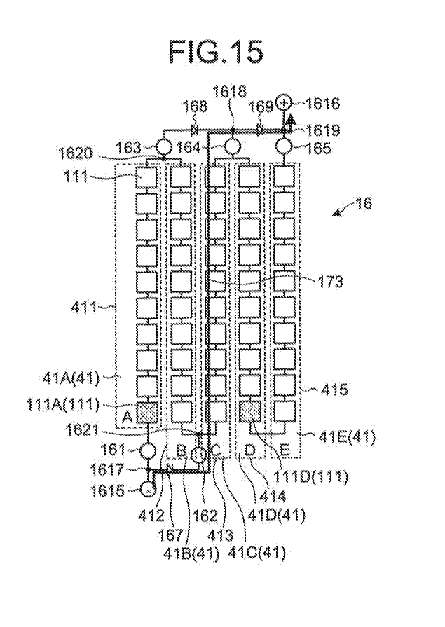

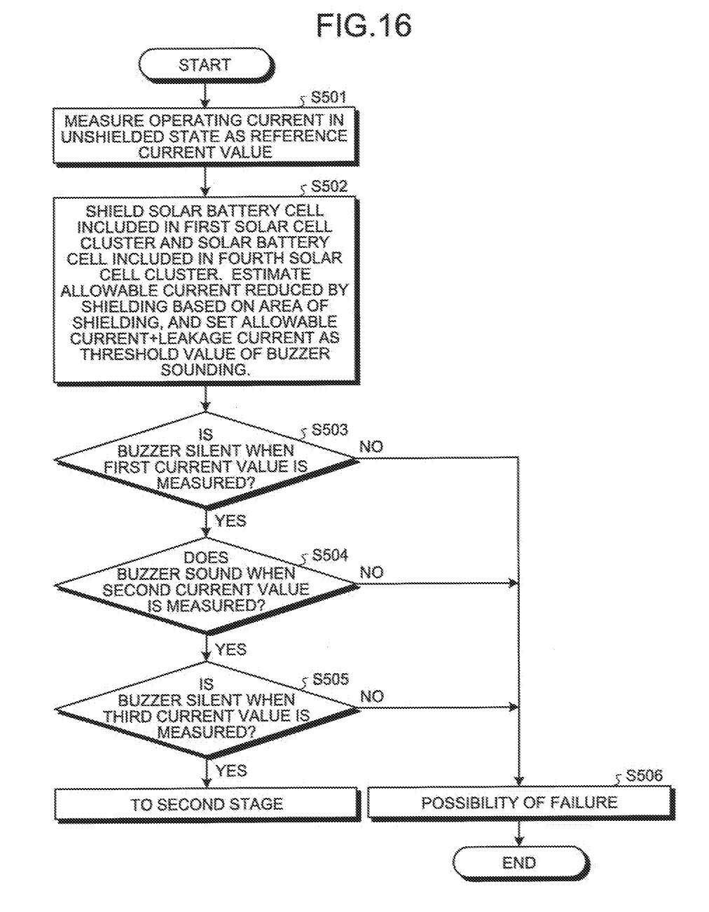

FIG. 15 is a diagram illustrating the first stage in an example of the method of inspecting a solar cell module according to the second embodiment. FIG. 16 is a flowchart illustrating the processing flow of the first stage in the example of the method of inspecting a solar cell module according to the second embodiment. In step S501, in the solar call module 16 operating as a part of the photovoltaic power generation system, the operating current is measured in the unshielded state as a reference current value. In step S502, in the solar cell module 16 operating as a part of the photovoltaic power generation system, the solar battery cell 111A included in the cluster 41A and the solar battery cell 111D included in the cluster 41D are shielded. The first solar cell cluster 411 and the fourth solar cell cluster 414 are shielded. The shielded state of the solar battery cells 111A and 111D is such that the entire surface of each cell is covered with a black rubber sheet having a thickness of about 5 mm, and no sunlight enters the shielded solar battery cells 111A and 111D at all. In this state, no current except the leakage current of the solar battery cell 111A flows in the cluster 41A that includes the shielded solar battery cell 111A, and the first bypass diode 167 operates. In addition, no current except the leakage current of the solar battery cell 111D flows in the cluster 41D that includes the shielded solar battery cell 111D and in the adjacent cluster 41E, and the third bypass diode 169 operates. A main current 173 of the circuit of the solar cell module 16 takes the following route: the negative terminal 1615, the branch point 1617, the first bypass diode 167, the second terminal portion 162, the branch point 1621, the cluster 41C, the fourth terminal portion 164, the branch point 1618, the third bypass diode 169, the branch point 1619, and the positive terminal 1616. Further, the allowable current reduced by shielding is estimated based on the area of shielding, and the sum of the allowable current and the leakage current is set as a threshold value of buzzer sounding.

Ideally, the threshold value is set in step S502 using the leakage current values of the solar battery cells 111A and 111D, but if the leakage current values of the solar battery cells 111A and 111D are not known, the threshold value may b set using a specification value.

In step S503, the first current value is measured by scanning the wires located in the first solar cell cluster 411 using a current sensor that detects a current with a change in the magnetic field and sounds a buzzer in response to the current exceeding the threshold value set in step S502, and it is checked whether the buzzer is silent when the first, current value is measured. If the buzzer sounds when the first current value is measured,

“No” is selected in step S503. Therefore, the process proceeds to step S506, where it is determined that there is a possibility of failure, and the process is terminated. If the buzzer is silent when the first current value is measured, “Yes” is selected in step S503. Therefore, the process proceeds to step S504.

In step S504, the second current value is measured by scanning the wires located in the third solar cell cluster 413 using a current sensor that detects a current with a change in the magnetic field and sounds a buzzer in response to the current exceeding the threshold value set in step S502, and it is checked whether the buzzer sounds when the second current value is measured. If the buzzer does not sound when the second current value is measured, “No” is selected in step S504. Therefore, the process proceeds to step S506, where it is determined that there is a possibility of failure, and the process is terminated. If the buzzer sounds when the second current value is measured, “Yes” is selected in step S504. Therefore, the process proceeds to step S505.

In step S505, the third current value is measured by scanning the wires located in the fourth solar cell cluster 414 or the fifth solar cell cluster 415 using a current sensor that detects a current with a change in the magnetic field and sounds a buzzer in response to the current exceeding the threshold value set in step S502, and it is checked whether the buzzer is silent when the third current value is measured. If the buzzer sounds when the third current value is measured, “No” is selected in step S505. Therefore, the process proceeds to step S506, where it is determined that there is a possibility of failure, and the process is terminated. If the buzzer is silent when the third current value is measured, “Yes” is selected in step S505. Therefore, the process of the second stage to be described later is executed.

When an open fault occurs in the path connecting the branch point 1617, the first bypass diode 167, and the second terminal portion 162 in this order, the current flowing through the solar cell module 16 is forced to pass through the shielded cluster 41A. Therefore, the current in the cluster 41A is greater than the leakage current of the solar battery cell 111A, and the buzzer sounds.

When an open fault occurs in the path connecting the second terminal portion 162, the branch point 1621, the cluster 41C, the fourth terminal portion 164, and the branch point 161B in this order, the current in the cluster 41C is equal to or less than the leakage current of the solar battery cell 111A, and the buzzer does not sound.

When an open fault occurs in the path connecting the branch point 1618, the third bypass diode 169, and the branch point 1619 in this order, the current flowing through the solar cell module 16 is forced to pass through the shielded cluster 41D and the cluster 41E. Therefore, the current between the cluster 41D and the cluster 41E is greater than the leakage current of the solar battery cell 111D, and the buzzer sounds.

Thus, by shielding the solar battery cells 111A and 111D and measuring the currents of the first solar cell cluster 411, the third solar cell cluster 413, and the fourth solar cell cluster 414 or the fifth solar cell cluster 415, an open fault in the first bypass diode 167 and the third bypass diode 169 and an open fault in the second solar cell cluster 412 can be detected.

In the example of the method of inspecting a solar cell module according to the second embodiment, the entire surface of one solar battery cell 111A included in the cluster 41A and the entire surface of one solar battery cell 111D included in the cluster 41D are shielded. However, because the purpose of shielding is to operate the first bypass diode 167 and the third bypass diode 169 no restrictions are imposed on the shielding condition such as shielded area and shadow density for shielding as long as the condition for operating the first bypass diode 167 and the third bypass diode 169 is satisfied. However, it is possible to reduce the possibility of erroneous determination due to fluctuations in the amount of solar radiation by making determinations with one solar battery cell 111A and one solar battery cell 111D completely covered.

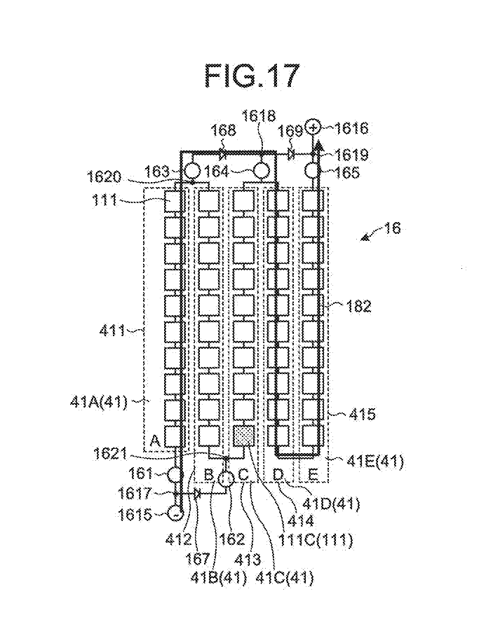

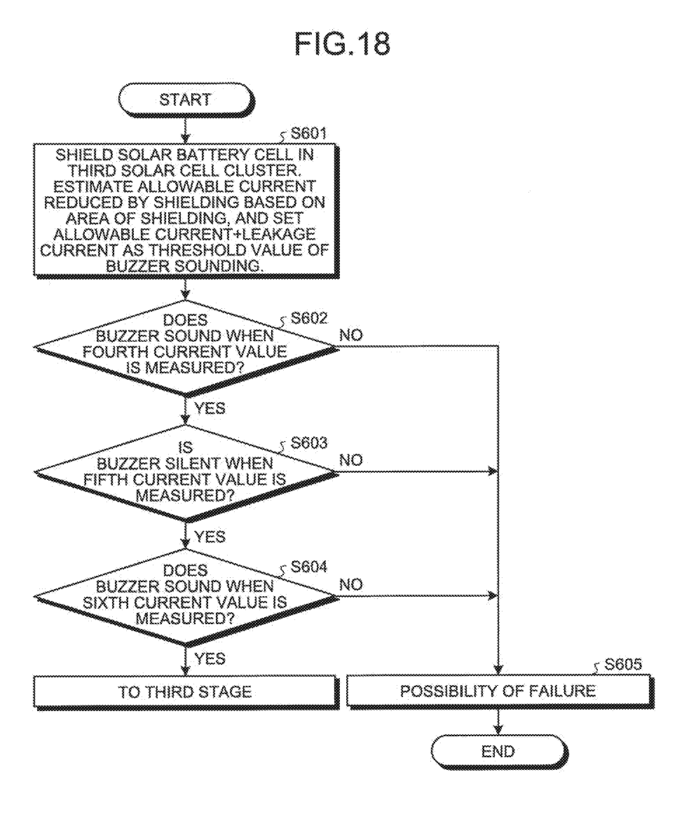

FIG. 17 is a diagram illustrating the second 2E stage in the example of the method of inspecting a solar cell module according to the second embodiment. FIG. 18 is a flowchart illustrating the processing flow of the second stage in the example of the method of inspecting a solar cell module according to the second embodiment. In step S601, in the solar cell module 16 operating as a part of the photovoltaic power generation system, the solar battery cell 111C included in the cluster 41C is shielded. That is, the third solar cell cluster 413 is shielded. The shielded state of the solar battery cell 111C is such that the entire surface of the cell is covered with a black rubber sheet having a thickness of about 5 mm, and no sunlight enters the shielded solar battery cell 111C at all. In this state, no current except the leakage current of the solar battery cell 111C flows in the second solar cell cluster 412 and the third solar cell cluster 413 including the shielded solar battery cell 111C, and the second bypass diode 168 operates. The flow of a main current 182 of the circuit of the solar cell module 16 takes the following route the negative terminal 1615, the branch point 1617, the first terminal portion 161, the cluster 41A, the third terminal portion 163, the second bypass diode 168, the branch point 1618, the fourth terminal portion 164, the cluster 41D, the cluster 41E, the fifth terminal portion 165, the branch point 1619, and the positive terminal 1616. Further, the allowable current reduced by shielding is estimated based on the area of shielding, and the sum of the allowable current and the leakage current is set as a threshold value of buzzer sounding.

Ideally, the threshold value is set in step S601 using the leakage current value of the solar battery cell 111C, but if the leakage current value of the solar battery cell 111C is not known, the threshold value may be set using a specification value.

In step S602, the fourth current value is measured by scanning the wires located in the first solar cell cluster 411 using a current sensor that detects a current with a change in the magnetic field and sounds a buzzer in response to the current exceeding the threshold value set in step S601, and it is checked whether the buzzer sounds when the fourth current value is measured. If the buzzer does not sound, when the fourth current value is measured, “No” is selected in step S602. Therefore, the process proceeds to step S605, where it is determined that there is a possibility of failure, and the process is terminated. If the buzzer sounds when the fourth current value is measured, “Yes” is selected in step S602. Therefore, the process proceeds to step S603.

In step S603, the fifth current value is measured by scanning the wires located in the second solar cell cluster 412 or the third solar cell cluster 413 using a current sensor that detects a current with a change in the magnetic field and sounds a buzzer in response to the current exceeding the threshold value set in step S601, and it is checked whether the buzzer is silent when the fifth current value is measured. If the buzzer sounds when the fifth current value is measured, “No” is selected in step S603. Therefore, the process proceeds to step S605, where it is determined that there is a possibility of failure, and the process is terminated. If the buzzer is silent when the fifth current value is measured, “Yes” is selected in step S603. Therefore, the process proceeds to step S604.

In step S604, the sixth current value is measured by scanning the wires located in the fourth solar cell cluster 414 or the fifth solar cell cluster 415 using a current sensor that detects a current with a change in the magnetic field and sounds a buzzer in response to the current exceeding the threshold value set in step S601, and it is checked whether the buzzer sounds when the sixth current value is measured. If the buzzer does not sound when the sixth current value is measured, “No” is selected in step S604. Therefore, the process proceeds to step S605 where it is determined that there is a possibility of failure, and the process is terminated. If the buzzer sounds when the sixth current value is measured, “Yes” is selected in step S604. Therefore, the process of the third stage to be described later is executed.

When an open fault occurs in the path connecting the negative terminal 1615, the branch point 1617, the first terminal portion 161, the cluster 41A, and the third terminal portion 163 in this order, the current in the cluster 41A is equal to or less than the leakage current, of the solar battery cell 111C, and the buzzer does not sound.

When an open fault occurs in the path connecting the third terminal portion 163, the second bypass diode 168, and the branch point 1618 in this order, the current flowing through the solar cell module 16 is forced to pass through the shielded cluster 41C and the adjacent cluster 41E. Therefore, the current from the cluster 41B to the cluster 41C is greater than the leakage current of the solar battery cell 1110, and the buzzer sounds.

When an open fault occurs in the path connecting the fourth terminal portion 164, the cluster 41D, the cluster 41E, the fifth terminal portion 165, the branch point 1619, and the positive terminal 1616, the current from the cluster 41D to the cluster 41E is equal to or less than the leakage current of the solar battery cell 111C, and the buzzer does not sound.

Thus, by shielding the solar battery cell 111C and measuring the fourth current value, the fifth current value, and the sixth current value, an open fault in the first solar cell cluster 411, the fourth solar cell cluster 414, or the fifth solar cell cluster 415 and an open fault in the second bypass diode 168 can be detected.

In the example of the method of inspecting a solar cell module according to the second embodiment, the entire surface of on a solar battery cell 111C included in the cluster 41C is shielded. However, because the purpose of shielding is to operate the second bypass diode 168, no restrictions are imposed on the shielding condition such as shielded area and shadow density for shielding as long as the condition for operating the second bypass diode 168 is satisfied. However, it is possible to reduce the possibility of erroneous determination due to fluctuations in the amount of solar radiation by making determinations with one solar battery cell 111C completely covered.

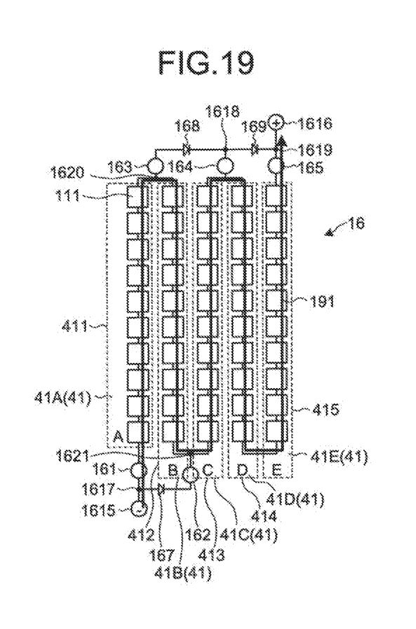

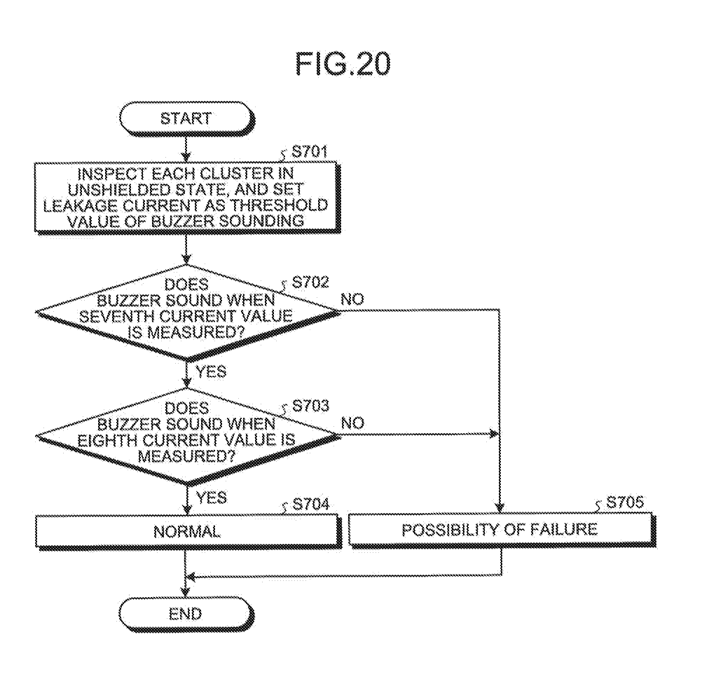

FIG. 19 is a diagram illustrating the third stage in the example of the method of inspecting a solar cell module according to the second embodiment. FIG. 20 is a flowchart illustrating the processing flow of the third stage in the example of the method of inspecting a solar cell module according to the second embodiment. In step S701, in the solar cell module 16 operating as a part of the photovoltaic power generation system, each cluster 41 is inspected in a state where none of the solar battery cells 111 is shielded, and the leakage current is set as a threshold value of buzzer sounding. A current 191 of the circuit of the solar cell module 16 takes the following route: the negative terminal 1615, the branch point 1617, the first terminal portion 161, the cluster 41A, the cluster 41B, the cluster 41C, the cluster 41D, the cluster 41E, the fifth terminal portion 165, the branch point 1619, and the positive terminal 1616.

Ideally, the threshold value is set in step S701 to the leakage current value of the solar battery cell 111 in the solar cell module 16, but if the leakage current value of the solar battery cell 111 in the solar cell module 16 is not known, a specification value may be used.

In step S702, a seventh current value is measured by scanning the wires located in the second solar cell cluster 412 using a current sensor that detects a current with a change in the magnetic field and sounds a buzzer in response to the current exceeding the threshold value set in step S701, and it is checked whether the buzzer sounds when the seventh current value is measured, if the buzzer does not sound when the seventh current value is measured, “No” is selected in step S702. Therefore, the process proceeds to step S705, where it is determined that there is a possibility of failure, and the process is terminated. If the buzzer sounds when the seventh current value is measured, “Yes” is selected in step S702. Therefore, the process proceeds to step S703.

In step S703, an eighth current value is measured by scanning the wires located in the fourth solar cell cluster 414 or the fifth solar cell cluster 415 using a current sensor that detects a current with a change in the magnetic field and sounds a buzzer in response to the current exceeding the threshold value set in step S701, and it is checked whether the buzzer sounds when the eighth current value is measured, if the buzzer does not sound when the eighth current value is measured, “No” is selected in step S703. Therefore, the process proceeds to step S705, where it is determined that there is a possibility of failure, and the process is terminated. If the buzzer sounds when the eighth current value is measured, “Yes” is selected in step S703. Therefore, it is determined in step S704 that the solar cell module 16 is normal, and the process is terminated.

When a short-circuit fault occurs at the first bypass diode 167 or the second bypass diode 168, or when an open fault occurs in the path connecting the branch point 1620, the cluster 41B, and the branch point 1621 in this order, the current in the cluster 41B is equal to or less than the leakage current of the solar battery cell 111 in the solar cell module 16, and the buzzer does not sound.

When a short-circuit fault occurs at the third bypass diode 169, the current between the cluster 41D and the cluster 41E is equal to or less than the leakage current of the solar battery cell 111 in the solar cell module 16, and the buzzer does not sound.

Thus, by measuring the seventh current value and the eighth current value, a short-circuit fault in the first bypass diode 167, the second bypass diode 168, or the third bypass diode 169 and an open fault in the second solar cell cluster 412 can be detected.

By performing the operation according to the flowcharts illustrated in FIGS. 16, 18, and 20, in the solar cell module including five clusters each including ten solar battery cells connected in series, the presence or absence of an open fault and a short-circuit fault in the circuit inside the module can be checked.

The method of inspecting a solar cell module according to the second embodiment enables detection of an open fault and a short-circuit fault in a circuit of a solar cell module with a simple technique without adding any parts to the solar cell module. Moreover, because the solar cell module can be inspected during the operation of the photovoltaic power generation system, a large-scale system stop is unnecessary, and it is possible to effectively utilize generated electric power. Therefore, the method of inspecting a solar cell module according to the second embodiment can reduce the opportunity loss of electric power selling in the case of selling electric power.

In the example of the method of inspecting a solar cell module according to the first embodiment and the example of the method of inspecting a solar cell module according to the second embodiment, a measuring device that sounds a buzzer in response to the current exceeding a certain threshold value is used. Alternatively, determinations may be made by a program or the like created to make determinations based on measured current values.

Further, in the example of the method of inspecting a solar cell module according to the first embodiment and the example of the: method of inspecting a solar cell module according to the second embodiment, a sensor that detects a current with a change in the magnetic field without making contact is described. Alternatively, it is also possible: to employ a current measuring method known in the field of electricity. For example, detection can be performed with techniques such as cutting a circuit and connecting testers in series or holding a circuit to be measured with a clamp tester.

The configuration described in the above-mentioned embodiments indicates an example of the contents of the present invention. The configuration can be combined with another well-known technique, and a part of the configuration can be omitted or changed in a range not departing from the gist of the present invention.

### REFERENCE SIGNS LIST

11, 16 solar cell module; 12 string; 13 junction box; 14 current collecting box; 15 power conditioner; 17 grid; 41, 41A, 41B, 41C, 41D, 41E, 41F cluster; 42, 1615 negative terminal; 43, 1616 positive terminal; 44, 161 first terminal portion; 45, 162 second terminal portion; 46, 163 third terminal portion; 47, 164 fourth terminal portion; 48, 167 first bypass diode; 49, 168 second bypass diode; 51 shadow portion; 53, 54, 63, 72, 81, 89, 122, 133, 173 182, 191, 610, 810 currents 71 sensor; 111, 111A, 111C, 111D, 111E solar battery cell; 165 fifth terminal portion; 169, 410 third bypass diode; 411 first solar cell cluster; 412 second solar cell cluster; 413 third solar cell cluster; 414 fourth solar cell cluster; 415 fifth solar cell cluster; 1117, 1118, 1119, 1120, 1617, 1618, 1619, 1620, 1621 branch point.

1. A method of inspecting a solar cell module for inspecting a solar cell module having a circuit in which a solar cell array that includes a plurality of clusters connected in series, a bypass diode connected in parallel to the clusters, and a terminal portion arranged between each of the clusters and the bypass diode, the plurality of clusters each including a plurality of solar battery cells connected in series, the method comprising
measuring a current value of a current flowing through the circuit using a sensor without making contact with the circuit to detect a short-circuit fault and an open fault in the circuit.

2. The method of inspecting a solar cell module according to claim 1, wherein
on a basis of a measurement result of a current value of a current flowing through the circuit in a state where the bypass diode is operated and a measurement result of a current value of a current flowing through the circuit in a state where the bypass diode is not operated, a short-circuit fault and an open fault in the circuit are detected.

3. The method of inspecting a solar cell module according to claim 2, wherein
the bypass diode is operated by shielding the solar cell module.

4. The method of inspecting a solar cell module according to claim 3, wherein
the bypass diode is operated by shielding an entire surface of one of the solar battery cells.

5. The method of inspecting a solar cell module according to claim 3, wherein
the bypass diode is operated by partially shielding one of the solar battery cells.

6. A method of inspecting a solar cell module including a solar cell array and a bypass diode, the solar cell array including a plurality of clusters connected in series, the plurality of clusters each including a plurality of solar battery cells connected in series, the bypass diode being connected in parallel to the clusters to cause a current that is unable to flow through the clusters to bypass the clusters when an amount of current that is able to flow through the clusters decreases, the method comprising:
a step of operating the bypass diode by reducing an allowable current of at least one of the solar battery cells in part of the plurality of clusters;
a step of setting, as a threshold value, a sum of the reduced allowable current of one of the solar battery cells and a leakage current of the solar battery cells; and
a step of determining that the solar cell module is abnormal when a current flowing through the clusters including the solar battery cells with the reduced allowable current is equal to or greater than the threshold value, or when a current flowing through another cluster that does not include the solar battery cells with the reduced allowable current is less than the threshold value, in a state where the bypass diode is in operation.

7. The method of inspecting a solar cell module according to claim 6, wherein
the allowable current is reduced by shielding some of the clusters.

8. The method of inspecting a solar cell module according to claim 7, wherein
the allowable current is reduced by shielding an entire surface of one of the solar battery cells.

9. The method of inspecting a solar cell module according to claim 7, wherein
the allowable current is reduced by partially shielding one of the solar battery cells.

10. The method of inspecting a solar cell module according to any one of claim 6, wherein
the threshold value is set to a value obtained by adding the leakage current of one of the solar battery cells and the allowable current of the solar battery cells partially shielded.

11. The method of inspecting a solar cell module according to claim 10, wherein
an inspection is performed by scanning a wire visible from a front or back surface of the solar cell module using a measuring device, which incorporates a sensor that detects a value of a current with a fluctuation in a magnetic field and informs a measurer in response to the value exceeding the threshold value.

12. A method of inspecting a solar cell module for inspecting a solar cell module, the solar cell module comprising:
a solar cell array that includes a first solar cell cluster, a second solar cell cluster, and a third solar cell cluster sequentially connected in series, the solar cell clusters each including a plurality of solar battery cells connected in series;
a first terminal portion connected to an end of the first solar cell cluster;
a second terminal portion connected to a connection between the first solar cell cluster and the second solar cell cluster;
a third terminal portion connected to a connection between the second solar cell cluster and the third solar cell cluster;
a fourth terminal portion connected to an end of the third solar cell cluster;
a first bypass diode connecting the first terminal portion and the second terminal portion;
a second bypass diode connecting the second terminal portion and the third terminal portion; and
a third bypass diode connecting the third terminal portion and the fourth terminal portion, wherein the method includes:
a step of measuring a reference current value flowing through the solar cell module without shielding the first solar cell cluster, the second solar cell cluster, and the third solar cell cluster;
a step of measuring a first current value flowing through the first solar cell cluster, a second current value flowing through the second solar cell cluster, and a third current value flowing through the third solar cell cluster in a state where one of the solar battery cells included in the second solar cell cluster is shielded, and detecting an open fault in the first solar cell cluster or a short-circuit fault in the first bypass diode, an open fault in the second bypass diode, and an open fault in the third solar cell cluster or a short-circuit fault in the third bypass diode by comparing each of the first current value, the second current value, and the third current value with a threshold value obtained by adding an allowable current that is estimated based on a shielded state of the second solar cell cluster and the reference current value, to a leakage current of one of the solar battery cells; and
a second fault detecting step of measuring a fourth current value flowing through the first solar cell cluster, a fifth current value flowing through the second solar cell cluster, and a sixth current value flowing through the third solar cell cluster in a state where at least one of the solar battery cells included in the first solar cell cluster and at least one of the solar battery cells included in the third solar cell cluster are shielded, and detecting an open fault in the first bypass diode, an open fault in the second solar cell cluster or a short-circuit fault in the second bypass diode, and an open fault in the third bypass diode by comparing each of the fourth current value, the fifth current value, and the sixth current value with a threshold value obtained by adding an allowable current estimated based on a shielded state of the first solar cell cluster and the third solar cell cluster and the reference current value to a leakage current of one of the solar battery cells.

13-14. (canceled)

15. The method of inspecting a solar cell module according to claim 7, wherein the threshold value is set to a value obtained by adding the leakage current of one of the solar battery cells and the allowable current of the solar battery cells partially shielded.

16. The method of inspecting a solar cell module according to claim 8, wherein the threshold value is set to a value obtained by adding the leakage current of one of the solar battery cells and the allowable current of the solar battery cells partially shielded.

17. The method of inspecting a solar cell module according to claim 9, wherein the threshold value is set to a value obtained by adding the leakage current of one of the solar battery cells and the allowable current of the solar battery cells partially shielded.
